(19) United States
(12) Patent Application Publication
(10) Pub. No.: US 2024/0413272 A1
(43) Pub. Date: Dec. 12, 2024

(54) WAVELENGTH CONVERTER AND WAVELENGTH CONVERSION MATERIAL USING THE SAME

(71) Applicant: SHIN-ETSU CHEMICAL CO., LTD., Tokyo (JP)

(72) Inventors: Kazuya TOBISHIMA, Annaka-shi (JP); Yoshihiro NOJIMA, Annaka-shi (JP); Shinji AOKI, Annaka-shi (JP)

(73) Assignee: SHIN-ETSU CHEMICAL CO., LTD., Tokyo (JP)

(21) Appl. No.: 18/704,142

(22) PCT Filed: Oct. 11, 2022
(86) PCT No.: PCT/JP2022/037830

§ 371 Date: Apr. 24, 2024

(30) Foreign Application Priority Data
Nov. 5, 2021 (JP) 2021-180909

(51) Int. Cl. H01L 33/50

(52) U.S. Cl. CPC H01L 33/502

(57) ABSTRACT

A wavelength converter including, as semiconductor nanoparticles, a first semiconductor nanoparticle that converts light with a wavelength of 450 nm into light with a wavelength λ₁ nm, and a second semiconductor nanoparticle that converts light with a wavelength of 450 nm into light with a wavelength λ₂ nm, in which the wavelength λ₁ and the wavelength λ₂ satisfy λ₁>λ₂>450, and a relation between an emission intensity I_{1b} and an emission intensity I1a satisfies I₁ₐ<I_{1b}, where I_{1b} is an emission intensity at the wavelength λ₁ when the wavelength converter including the first and second semiconductor nanoparticles is irradiated with light with a wavelength of 450 nm and an excitation photon number N₀, and I₁ₐ is an emission intensity at the wavelength λ₁ when a wavelength converter including only the first semiconductor nanoparticle is irradiated with the light with a wavelength of 450 nm and an excitation photon number N₀.

### TECHNICAL FIELD

The present invention relates to a wavelength converter and a wavelength conversion material using the same.

### BACKGROUND ART

In semiconductor particles having nanosized particle diameters, excitons formed by light absorption are confined in nanosized space so that energy levels of the semiconductor nanoparticles become discrete, and their band gap depends on particle diameters. Thus, the fluorescence emission of the semiconductor nanoparticles has high efficiency and the emission spectrum is sharp. Further, because of the characteristic of changing band gap with particle diameters, semiconductor nanoparticles have a feature of being capable of controlling emission wavelength and are expected to find applications for solid-state lighting and displays as a wavelength conversion material (Patent Document 1).

Semiconductor nanoparticles containing Cd are an example of quantum dots exhibiting excellent fluorescence emission characteristics. However, Cd is toxic to human bodies and environment and its use is restricted by RoHS adopted in the European Union as well as around the world. Therefore, semiconductor nanoparticles containing no harmful substances such as Cd have been explored. Semiconductor nanoparticles having InP as light emission center have been developed as one of alternative materials.

Furthermore, material development for color filter applications using semiconductor nanoparticles as a wavelength conversion material has been undertaken, in which a wavelength conversion layer with a resin composition containing semiconductor nanoparticles and a resin is formed and patterned on a transparent substrate. A color filter in conventional liquid crystal displays is a thin-film optical component in which blue, green, and red pixel portions having a pixel size of tens to hundreds micrometers are regularly arranged on a transparent substrate, and a black matrix is disposed between the pixels in order to prevent color mixing between pixels. The color filter enables display of an image in units of minute pixels by extracting three kinds of light, namely, red, green, and blue from white light.

When semiconductor nanoparticles are used for color filter applications, as an example, wavelength conversion layers made of semiconductor nanoparticles emitting green or red light and a resin are regularly arranged and combined with a blue light source to form light-emitting elements. With such a structure, blue light which is excitation light can be converted by each wavelength conversion layer into green or red light, and because of the characteristics of a narrow full width at half maximum of emission and high conversion efficiency, the semiconductor nanoparticles are expected to improve color reproducibility and luminance of displays.

### CITATION LIST

### Patent Literature

Patent Document 1: JP 2012-022028 A

### SUMMARY OF INVENTION

### Technical Problem

However, if the absorptance of semiconductor nanoparticles for blue light is not sufficient, the light extraction efficiency for green and red light decreases, and moreover, blue light is transmitted through the wavelength conversion layer to cause color mixing. Such color mixing imposes limitations on the reproducibility of color to be extracted, leading to poor image quality. Consequently, the color purity of the color filter is reduced.

When the wavelength conversion layer has a thickness of about 10 μm as in color filter applications, it is impossible to dispose many semiconductor nanoparticles in the optical path. Therefore, a material with a high absorptance for excitation light is sought for. Further, converting the absorbed excitation light with high efficiency can improve the light extraction efficiency from the wavelength conversion layer to the outside, resulting in a wavelength conversion material with excellent emission characteristics.

Semiconductor nanoparticles having InP as light emission center are known to have a lower absorption coefficient than semiconductor nanoparticles containing Cd. It has therefore been difficult to use them as a wavelength conversion material that is required to have high absorptance for blue light as in color filter applications.

In order to increase the absorptance of a wavelength conversion layer for blue light, one of improvement methods is to increase the optical path length of the wavelength conversion layer by introducing scattering particles such as inorganic oxide with a high refractive index into the wavelength conversion layer. However, introducing micrometer-sized particles that makes a significant scattering contribution into the wavelength conversion layer changes the thickness of the wavelength conversion layer or causes problems with color uniformity when the thickness and/or concentration of the wavelength conversion layer is adjusted. For this reason, merely with the method of using scattering particles, it is difficult to improve the absorptance of excitation light in the wavelength conversion layer and the light extraction efficiency after wavelength conversion.

The present invention is made to solve the above problem and aims to provide: a wavelength converter with improved absorptance for blue light and light extraction efficiency after wavelength conversion; and a wavelength conversion material in which the wavelength converter is dispersed in a resin.

### Solution to Problem

To achieve the object, the present invention provides a wavelength converter comprising, as semiconductor nanoparticles, a first semiconductor nanoparticle that converts light with a wavelength of 450 nm into light with a wavelength λ₁ nm, and a second semiconductor nanoparticle that converts light with a wavelength of 450 nm into light with a wavelength λ₂ nm, wherein the wavelength λ₁ and the wavelength λ₂ satisfy λ₁>λ₂>450, and a relation between an emission intensity I_{1b} and an emission intensity I₁ₐ satisfies I₁ₐ<I_{1b}, where I_{1b} is an emission intensity at the wavelength λ₁ when the wavelength converter comprising the first semiconductor nanoparticle and the second semiconductor nanoparticle is irradiated with light with a wavelength of 450 nm and an excitation photon number N₀, and I₁ₐ is an emission intensity at the wavelength λ₁ when a wavelength converter comprising only the first semiconductor nanoparticle as a semiconductor nanoparticle is irradiated with the light with a wavelength of 450 nm and an excitation photon number N₀.

Such a wavelength converter improves the absorptance for blue light and the light extraction efficiency after wavelength conversion.

In the wavelength converter, the wavelength λ₁ may be included in a range of 510 to 550 nm or 610 to 650 nm.

With this configuration, blue light can be efficiently converted into green light or red light.

In the wavelength converter, the wavelength λ₁ may be included in a range of 510 to 550 nm, and the wavelength λ₂ may be included in a range of 480 to 510 nm. In the wavelength converter, the wavelength λ₁ may be included in a range of 510 to 550 nm, and the wavelength λ₂ may be included in a range of 490 to 500 nm.

With this configuration, blue light can be absorbed, light with wavelength λ₂ can be further converted into green light with wavelength λ₁ longer than the wavelength λ₂, and the extraction efficiency of light with wavelength λ₁ is further improved.

In the wavelength converter, the wavelength λ₁ may be included in a range of 610 to 650 nm, and the wavelength λ₂ may be included in a range of 480 to 600 nm. In the wavelength converter, the wavelength λ₁ may be included in a range of 610 to 650 nm, and the wavelength λ₂ may be included in a range of 490 to 500 nm or 590 to 600 nm.

With this configuration, blue light can be absorbed, light with wavelength λ₂ can be further converted into red light with wavelength λ₁ longer than the wavelength λ₂, and the extraction efficiency of light with wavelength λ₁ is further improved.

In the wavelength converter, the first semiconductor nanoparticle may be a semiconductor nanoparticle comprising a core semiconductor containing In and P, and a single or multiple shell semiconductors covering the core semiconductor.

With this configuration, the first semiconductor nanoparticle and the wavelength converter have a structure free from harmful substances such as Cd and Pb.

In the wavelength converter, the shell semiconductor of the first semiconductor nanoparticle may comprise any one semiconductor or a mixed crystal of a plurality of semiconductors selected from the group consisting of ZnS, ZnSe, ZnTe, AlN, AlP, AlAs, AlSb, GaN, GaP, GaAs, GaSb, InN, InP, InAs, and InSb.

With this configuration, the emission efficiency and the stability are further improved.

In the wavelength converter, the second semiconductor nanoparticle may comprise a core semiconductor containing Zn, Se, and Te, and a single or multiple shell semiconductors covering the core semiconductor. In the wavelength converter, the second semiconductor nanoparticle may comprise a core semiconductor containing Zn and P, and a single or multiple shell semiconductors covering the core semiconductor.

With this configuration, the absorptance for blue light is further improved.

In the wavelength converter, the second semiconductor nanoparticle may comprise a core semiconductor that is a compound with a chalcopyrite structure, and a single or multiple shell semiconductors covering the core semiconductor. In the wavelength converter, the second semiconductor nanoparticle may comprise a core semiconductor comprising any one semiconductor or a mixed crystal of a plurality of semiconductors selected from the group consisting of AgGas₂, AgInS₂, AgGaSe₂, AgInSe₂, CuGaS₂, CuGaSe₂, CuInS₂, CuInS₂, ZnSiP₂, and ZnGeP₂, and a single or multiple shell semiconductors covering the core semiconductor.

With this configuration, the absorptance for blue light is further improved.

In the wavelength converter, the shell semiconductor of the second semiconductor nanoparticle may comprise a II-VI compound semiconductor. In the wavelength converter, the shell semiconductor of the second semiconductor nanoparticle may comprise any one semiconductor or a mixed crystal of a plurality of semiconductors selected from the group consisting of ZnSe and ZnS.

Such a configuration is particularly preferred in terms of improving emission efficiency and stability.

In the wavelength converter, a dispersion liquid in which 1.0 mg of the first semiconductor nanoparticle is dispersed in 1.0 mL of a solvent may have an absorbance of 0.7 or more at an optical path length of 1 cm for light with a wavelength of 450 nm.

With this configuration, the absorptance for blue light is improved, and the light extraction efficiency of light with wavelength λ₁ is improved.

In the wavelength converter, a dispersion liquid in which 1.0 mg of the second semiconductor nanoparticle is dispersed in 1.0 mL of a solvent may have an absorbance of 1.0 or more, preferably 1.2 or more, more preferably 1.4 or more at an optical path length of 1 cm for light with a wavelength of 450 nm.

With this configuration, the absorptance for blue light is improved, and the extraction efficiency of light with wavelength λ₂ is improved, and light with wavelength λ₂ is further converted into wavelength λ₁ whereby the extraction efficiency of light with wavelength λ₁ is further improved.

In the wavelength converter, the first semiconductor nanoparticle may have an internal quantum efficiency of 70% or more. In the wavelength converter, the second semiconductor nanoparticle may have an internal quantum efficiency of 40% or more.

With this configuration, the light extraction efficiency is further improved.

In the wavelength converter, a mass ratio of the second semiconductor nanoparticle to the first semiconductor nanoparticle may have a value of 0.3 or less.

Within such a range of mass ratio, leakage of light with wavelength λ₂, which is emission of the second semiconductor nanoparticle from the wavelength converter, can be more effectively prevented, and only the light with wavelength λ₁ can be stably extracted.

A wavelength conversion material in which the above wavelength converter is dispersed in a resin may be provided.

With such a wavelength conversion material, the absorptance for blue light and the light extraction efficiency after wavelength conversion are improved.

### Advantageous Effects of Invention

As described above, the wavelength converter of the present invention improves the absorptance for blue light and the light extraction efficiency after wavelength conversion.

### BRIEF DESCRIPTION OF DRAWINGS

FIG. 1 schematically shows wavelength conversion by a wavelength converter according to the present invention;

FIG. 2 schematically shows wavelength conversion in a first semiconductor nanoparticle; and

FIG. 3 schematically shows wavelength conversion in a second semiconductor nanoparticle.

### DESCRIPTION OF EMBODIMENTS

The present invention will be described in detail below. However, the present invention is not limited thereto.

As described above, a wavelength converter with improved absorptance for blue light and light extraction efficiency after wavelength conversion has been sought for.

The inventors of the present invention have conducted elaborate studies for the above object and found that the absorptance for blue light and the light extraction efficiency after wavelength conversion are improved by a wavelength converter comprising, as semiconductor nanoparticles, a first semiconductor nanoparticle that converts light with a wavelength of 450 nm into light with a wavelength λ₁ nm, and a second semiconductor nanoparticle that converts light with a wavelength of 450 nm into light with a wavelength λ₂ nm, wherein the wavelength λ₁ and the wavelength λ₂ satisfy λ₁>λ₂>450, and a relation between an emission intensity I_{1b} and an emission intensity I₁ₐ satisfies I₁ₐ<I_{1b}, where I_{1b} is an emission intensity at the wavelength λ₁ when the wavelength converter comprising the first semiconductor nanoparticle and the second semiconductor nanoparticle is irradiated with light with a wavelength of 450 nm and an excitation photon number N₀, and I₁ₐ is an emission intensity at the wavelength λ₁ when a wavelength converter comprising only the first semiconductor nanoparticle as a semiconductor nanoparticle is irradiated with the light with a wavelength of 450 nm and an excitation photon number No. This finding has led to completion of the invention.

A description will be given below with reference to the drawings. In the present invention, “convert into light of λ nm” means conversion into light with an emission wavelength having a peak near λ nm.

### Wavelength Converter

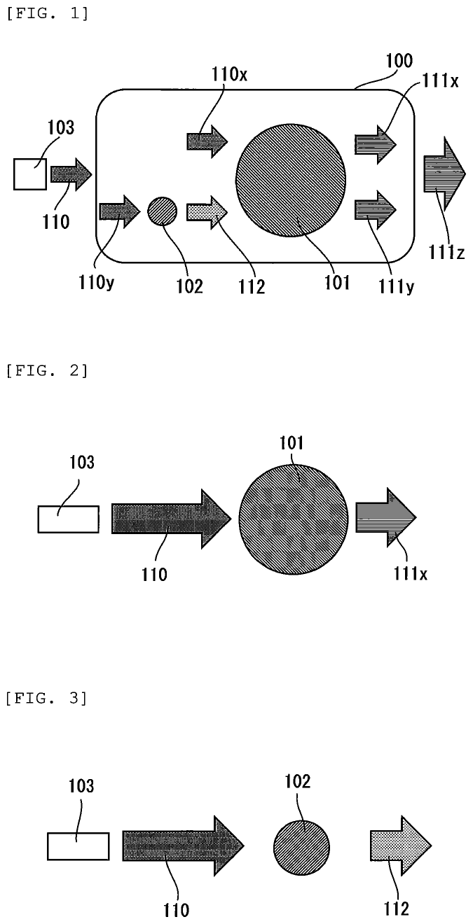

FIG. 1 schematically shows wavelength conversion by a wavelength conversion material containing a wavelength converter according to the present invention. As illustrated in FIG. 1, a wavelength converter 100 according to the present invention contains a first semiconductor nanoparticle 101 and a second semiconductor nanoparticle 102.

As schematically illustrated in FIG. 2, part of light 110 with a wavelength of 450 nm emitted from a blue LED light source 103 is absorbed by the first semiconductor nanoparticle 101 and becomes light 111x with a wavelength λ₁ converted from light with a wavelength of 450 nm by the first semiconductor nanoparticle 101.

Similarly, as schematically illustrated in FIG. 3, part of light 110 with a wavelength of 450 nm emitted from the blue LED light source 103 is absorbed by the second semiconductor nanoparticle 102 and becomes light 112 with a wavelength λ₂ converted from light with a wavelength of 450 nm by the second semiconductor nanoparticle 102.

When such a wavelength converter 100 containing the first semiconductor nanoparticle 101 and the second semiconductor nanoparticle 102 is irradiated with, for example, light with a wavelength of 450 nm from a light source such as the blue LED light source 103, as illustrated in FIG. 1, part of light 110 with a wavelength of 450 nm emitted from the blue LED light source (light 110x with a wavelength of 450 nm to be absorbed by the first semiconductor nanoparticle) is absorbed by the first semiconductor nanoparticle 101, and part of light 110 (light 110y with a wavelength of 450 nm to be absorbed by the second semiconductor nanoparticle) is absorbed by the second semiconductor nanoparticle 102. Light 110x with a wavelength of 450 nm to be absorbed by the first semiconductor nanoparticle becomes light 111x with wavelength λ₁ converted from light with a wavelength of 450 nm by the first semiconductor nanoparticle 101, in the same manner as in FIG. 2.

Light 110y with a wavelength of 450 nm to be absorbed by the second semiconductor nanoparticle becomes light 112 with wavelength λ₂ converted from light with a wavelength of 450 nm by the second semiconductor nanoparticle 102, in the same manner as in FIG. 3. In this case, if the wavelengths λ₁ and λ₂ have a relation of λ₁>λ₂>450 nm, light 112 with wavelength λ₂ converted from light with a wavelength of 450 nm is further absorbed by the first semiconductor nanoparticle 101 and becomes light 111y with wavelength λ₁ converted from light with wavelength λ₂ by the first semiconductor nanoparticle 101.

As a result, light 111z with wavelength λ₁ extracted from the wavelength converter to the outside is the sum of light 111x with wavelength λ₁ converted from light with a wavelength of 450 nm and light 111y with wavelength λ₁ converted from light with wavelength λ₂. In other words, the relation between the emission intensity I_{1b} at wavelength λ₁ when the wavelength converter 100 containing the first semiconductor nanoparticle 101 and the second semiconductor nanoparticle 102 is irradiated with light with a wavelength of 450 nm and an excitation photon number N₀ and the emission intensity I₁ₐ at wavelength λ₁ when a wavelength converter containing only the first semiconductor nanoparticle 101 as semiconductor nanoparticle is irradiated with light with a wavelength of 450 nm and an excitation photon number No satisfies I₁ₐ<I_{1b}. In other words, the absorptance for blue light is improved, and the extraction efficiency of light with wavelength λ₁ extracted from the wavelength converter to the outside is improved.

In this way, the inventors of the present invention have found that the absorptance for blue light and the light extraction efficiency can be improved by using the wavelength converter 100 containing the first semiconductor nanoparticle 101 and the second semiconductor nanoparticle 102 described above.

The light with wavelength λ₁ is preferably green light or red light, and the value of wavelength λ₁ is preferably in the range of 510 to 550 nm or 610 to 650 nm. By using the first semiconductor nanoparticle having such a value of wavelength λ₁, the wavelength converter serves as a wavelength converter that efficiently converts blue light into green light or red light.

Further, when wavelength λ₁ is 510 to 550 nm, the value of wavelength λ₂ is preferably 480 to 510 nm and more preferably 490 to 500 nm. When wavelength λ₂ falls within such a range of values, blue light can be absorbed and light with wavelength λ₂ can be further converted into green light with wavelength λ₁ longer than wavelength λ₂, resulting in a wavelength converter with more improved extraction efficiency of light with wavelength λ₁.

When wavelength λ₁ is 610 to 650 nm, the value of wavelength λ₂ is preferably 480 to 600 nm and more preferably 490 to 500 nm or 590 to 600 nm. When wavelength λ₂ falls within such a range of values, blue light can be absorbed and light with wavelength λ₂ can be further converted into red light with wavelength λ₁ longer than wavelength λ₂, resulting in a wavelength converter with more improved extraction efficiency of light with wavelength λ₁.

The first and second semiconductor nanoparticles according to the present invention are not limited to any particular structure but preferably are semiconductor nanoparticles with a core-shell structure in terms of fluorescence emission characteristics and stability. In other words, it is preferable to include a core semiconductor which is a nanoparticle and single or multiple shell semiconductors covering the core semiconductor. In a semiconductor nanoparticle having a core/shell structure in which the core is a nanosized semiconductor particle and the shell is a semiconductor with a band gap larger than that of the core and a low lattice mismatch, an exciton produced in the shell is confined inside the core particle, so that the fluorescence emission efficiency is improved and, in addition, the stability is improved because the core surface is covered with the shell.

The first semiconductor nanoparticle is not limited to any particular composition but an example includes a material with In and P as a core. With such a composition, the first semiconductor nanoparticle and the wavelength converter are materials free from harmful substances such as Cd and Pb.

The shell material of the first semiconductor nanoparticle is not limited but preferably those with a large band gap relative to the core material and a low lattice mismatch, and an alloy or a mixed crystal of semiconductors of II-VI compounds and III-V compounds is selected. A specific shell material may be selected as any one semiconductor or a mixed crystal of a plurality of semiconductors selected from ZnS, ZnSe, ZnTe, AlN, AlP, AlAs, AlSb, GaN, GaP, GaAs, GaSb, InN, InP, InAs, and InSb. Among these materials, ZnSe and ZnS are particularly preferred in terms of improving emission efficiency and stability.

The second semiconductor nanoparticle is not limited to any particular composition but a material that strongly absorbs blue light is preferred. Examples include materials containing Zn, Te, and Se as a core, materials containing Zn and P as a core, and materials containing tertiary compounds having a chalcopyrite structure as a core, such as AgGaS₂, AgInS₂, AgGaSe₂, AgInSe₂, CuGaS₂, CuGaSe₂, CuInS₂, CuInS₂, ZnSiP₂, and ZnGeP₂. The materials having such a composition are known to have a high absorption coefficient for blue light. When the second semiconductor nanoparticle has such a composition, the absorptance of the wavelength converter for blue light is improved.

The shell material of the second semiconductor nanoparticle is not limited but II-VI compounds are preferred. Among these materials, a semiconductor shell constituted with any one semiconductor or a mixed crystal of a plurality of semiconductors selected from ZnSe and ZnS is particularly preferable in terms of improving emission efficiency and stability.

There are various methods for producing semiconductor nanoparticles, such as a liquid phase method and a gas phase method, and the semiconductor nanoparticle according to the present invention is not limited to any particular method. In terms of exhibiting high fluorescence emission efficiency, it is preferable to use semiconductor nanoparticles obtained using a hot soap method or a hot injection method in which a precursor species is reacted at a high temperature in a non-polar solvent with a high boiling point.

In order to reduce surface defects, it is preferable that an organic ligand called ligand coordinates to the surface of the semiconductor nanoparticle. The ligand preferably contains an aliphatic hydrocarbon in terms of suppressing agglomeration of semiconductor nanoparticles. Examples of such a ligand include oleic acid, stearic acid, palmitic acid, myristic acid, lauric acid, decanoic acid, octanoic acid, oleylamine, stearyl(octadecyl)amine, dodecyl(lauryl)amine, decylamine, octylamine, octadecanthiol, hexadecanthiol, tetradecanthiol dodecanethiol, decanethiol, octanthiol, trioctylphosphine, trioctylphosphine oxide, triphenylphosphine, triphenylphosphine oxide, tributylphosphine, and tributylphosphine oxide. These may be used singly or in combination of two or more.

It is preferable that the first semiconductor nanoparticle has an internal quantum efficiency of 70% or more. Further, it is preferable that the second semiconductor nanoparticle has an internal quantum efficiency of 40% or more. The light extraction efficiency of light with wavelength λ₁ is further improved. The upper limits of internal quantum efficiency of the first semiconductor nanoparticle and the second semiconductor nanoparticle are not limited but may be, for example, 100% or less and 70% or less, respectively.

The higher the absorbance of the first semiconductor nanoparticle for blue light, the more preferable. For example, when the first semiconductor nanoparticle is dispersed in 1.0 ml of a solvent, the absorbance for blue light with a wavelength of 450 nm at an optical path length of 1 cm is preferably 0.7 or more. The solvent is not limited but examples include non-polar solvents such as toluene and hexane. With such a semiconductor nanoparticle, the absorptance for blue light is further improved and the light extraction efficiency of light with wavelength λ₁ is further improved. The upper limit of the absorbance of the first semiconductor nanoparticle for blue light is not limited but may be, for example, 1.0 or less.

The higher the absorbance of the second semiconductor nanoparticle for blue light, the more preferable. For example, when the second semiconductor nanoparticle is dispersed in 1.0 ml of a solvent, the absorbance for blue light with a wavelength of 450 nm at an optical path length of 1 cm is preferably 1.0 or more, more preferably 1.2 or more, and even more preferably 1.4 or more. The solvent is not limited but examples include non-polar solvents such as toluene and hexane. With such a semiconductor nanoparticle, the absorptance for blue light is further improved, the extraction efficiency of light with wavelength λ₂ is further improved, and when the semiconductor nanoparticle is used as a wavelength converter, light with wavelength λ₂ is further converted into wavelength λ₁, whereby the extraction efficiency of light with wavelength λ₁ is further improved. The upper limit of the absorbance of the second semiconductor nanoparticle for blue light is not limited but may be, for example, 2.0 or less.

It is preferable that the wavelength converter has a higher absorptance when irradiated with blue excitation light. In particular, when the wavelength converter is applied to uses such as color filer, the absorptance for excitation light is preferably 90% or more and more preferably 95% or more.

If absorption of light with wavelength λ₂ by the first semiconductor nanoparticle is insufficient, light with λ₂ may leak to the outside of the wavelength converter. Leakage of light with wavelength λ₂ causes color mixing and reduces the color purity of an emission spectrum. In order to prevent leakage of light with wavelength λ₂ from the wavelength converter, it is preferable that the mass ratio of the second semiconductor nanoparticle to the first semiconductor nanoparticle has a value of 0.3 or less. Within such a range of mass ratio, leakage of light with wavelength λ₂, which is emission of the second semiconductor nanoparticle, from the wavelength converter can be effectively prevented, and only the light with wavelength λ₁ can be stably extracted to the outside. The lower limit of the value of mass ratio of the second semiconductor nanoparticle to the first semiconductor nanoparticle is not limited as long as it is greater than 0, but may be, for example, 0.01 or more, preferably 0.05 or more, and more preferably 0.1 or more.

The wavelength converter may include a semiconductor nanoparticle other than the first semiconductor nanoparticle and the second semiconductor nanoparticle described above.

### Wavelength Conversion Material

The wavelength converter may be used in the form of a wavelength conversion material in which the wavelength converter is dispersed in a resin. The resin material is not limited, but those that do not cause agglomeration of the wavelength converter or deterioration in fluorescence emission efficiency are preferred. Examples include silicone resin, acrylic resin, epoxy resin, urethane resin, and fluororesin. It is preferable that these materials have a high transmittance in order to increase the fluorescence emission efficiency as the wavelength conversion material, and the transmittance is particularly preferably 80% or more. With such a wavelength conversion material, the absorptance for blue light and the light extraction efficiency after wavelength conversion are improved.

In the wavelength conversion material according to the present invention, it is preferable that the proportion of the wavelength converter is from 15% by mass to 65% by mass. With such a range, the wavelength conversion material in which the absorptance for blue light is stably higher is provided. When the proportion of the wavelength converter in the wavelength conversion material is 70% by mass or less, insufficient curing caused by a lower proportion of the resin component can be stably prevented. In these respects, it is more preferable that the proportion of the wavelength converter in the wavelength conversion material is 20 to 60% by mass.

The wavelength conversion material may additionally contain a scattering particle. When the wavelength conversion material contains a scattering particle with a high refractive index, excitation light is scattered so that the substantial optical path length in the wavelength conversion layer can be increased, and the light extraction efficiency is further improved. The scattering particle is not limited to any particular kind but examples include inorganic oxides. Specifically, examples include Al₂O₃, ZrO₂, TiO₂, SiO₂, MgO, Zno, BaTiO₃, and SnO. The scattering particle may be selected from one or more of these. As the size of the scattering particle, an average particle diameter of 50 to 1000 nm is preferred, and 100 to 500 nm is more preferred. Although depending on the particle diameter, the scattering particle is preferably in the amount of 1 to 30% by mass of the wavelength conversion material, more preferably 3 to 20% by mass, in terms of preventing turbidity of the wavelength conversion material.

### EXAMPLE

Although the present invention will be specifically described below with examples, the present invention is not intended to be limited by this.

Production and Evaluation of Semiconductor Nanoparticles

### (Measurement)

In fluorescence emission characteristics evaluation of semiconductor nanoparticles in Production Examples, emission wavelength peaks and internal quantum efficiency at an excitation wavelength of 450 nm were measured using a quantum efficiency measurement system (QE-2100: manufactured by Otsuka Electronics Co., Ltd.).

The absorbance of semiconductor nanoparticles was measured and evaluated using a UV-Visible/NIR spectrophotometer (V-750: manufactured by JASCO Corporation). In a 1 cm wide cell, 1.0 mg of semiconductor nanoparticles were dispersed in 1.0 mL of a toluene solvent, and the absorbance was evaluated.

### Production Example 1

In a flask, 0.070 g (0.24 mmol) of indium acetate, 0.256 g (0.72 mmol) of palmitic acid, and 4.0 mL of 1-octadecene were added and stirred with heating at 100° C. under reduced pressure, and degassed for one hour while dissolving. The flask was cooled to room temperature and then purged with nitrogen, and 0.50 mL (0.17 mmol) of a 10 vol % tris(trimethylsilyl)phosphine/octadecene solution was added to the flask. The flask was heated to 300° C. and stirring was performed for 20 minutes to synthesize core semiconductor nanoparticles. Subsequently, the flask was cooled to 200° C. and then 4.0 mL (1.2 mmol) of a 0.30 M zinc stearate/octadecene solution was added and stirred for 30 minutes. Further, 0.60 mL (0.90 mmol) of a selenium/trioctylphosphine solution 1.5 M was added to the flask and stirred for 30 minutes. The flask was then cooled to room temperature and then 0.22 g (1.2 mmol) of zinc acetate was added and stirred with heating at 100° C. under reduced pressure, and the solution was degassed for one hour while dissolving. The flask was purged with nitrogen and then heated to 230° C., and 0.48 mL (2.0 mmol) of 1-DDT (dodecanethiol) was added and stirred for 30 minutes. The resulting solution was cooled to room temperature and, with addition of ethanol, centrifuged to precipitate semiconductor nanoparticles, and the supernatant solution was removed. Toluene was further added to disperse the precipitate, ethanol was added again to perform centrifugation, and the supernatant solution was removed. The precipitate was dispersed again in toluene to prepare an InP/ZnSe/ZnS semiconductor nanoparticle toluene solution. The fluorescence emission wavelength peak of the solution was 534 nm, the internal quantum efficiency of the solution was 76%, and the absorbance for 450 nm light was 0.8.

### Production Example 2

In a flask, 0.175 g (0.6 mmol) of indium acetate, 0.640 g (1.8 mmol) of palmitic acid, and 10.0 mL of 1-octadecene were added and stirred with heating at 100° C. under reduced pressure, and degassed for one hour while dissolving. The flask was cooled to room temperature and then purged with nitrogen, and 1.0 mL (0.34 mmol) of a 10 vol % tris(trimethylsilyl)phosphine/octadecene solution was added to the flask. The flask was heated to 300° C. and stirring was performed for 30 minutes to synthesize core semiconductor nanoparticles. Subsequently, the flask was cooled to 200° C. and then 6.0 mL (1.8 mmol) of a 0.30 M zinc stearate/octadecene solution was added and stirred for 30 minutes. Further, 0.90 mL (1.35 mmol) of a selenium/trioctylphosphine solution 1.5 M was added to the flask and stirred for 30 minutes. The flask was then cooled to room temperature and then 0.44 g (2.4 mmol) of zinc acetate was added and stirred with heating at 100° C. under reduced pressure, and the solution was degassed for one hour while dissolving. The flask was purged with nitrogen and then heated to 230° C., and 0.96 mL (4.0 mmol) of 1-DDT (dodecanethiol) was added and stirred for 30 minutes. The resulting solution was cooled to room temperature and, with addition of ethanol, centrifuged to precipitate semiconductor nanoparticles, and the supernatant solution was removed. Toluene was further added to disperse the precipitate, ethanol was added again to perform centrifugation, and the supernatant solution was removed. The precipitate was dispersed again in toluene to prepare an InP/ZnSe/ZnS semiconductor nanoparticle toluene solution. The fluorescence emission wavelength peak of the solution was 622 nm, the internal quantum efficiency was 72%, and the absorbance for 450 nm light was 0.7.

### Production Example 3

In a flask, 0.066 g (0.36 mmol) of zinc acetate, 0.24 ml (0.76 mmol) of oleic acid, 4.0 ml of ODE, and 0.15 ml of oleylamine are added and stirred with heating at 100° C. under reduced pressure, and the solution was degassed for one hour. Subsequently, the flask was purged with nitrogen and heated to 260° C. When the temperature of the solution was stabilized, 0.70 mL (0.24 mmol) of a 10 vol % tris(trimethylsilyl)phosphine/octadecene solution was added to the flask. The flask was heated to 300° C. and the solution was stirred and held for 20 minutes to synthesize core semiconductor nanoparticles. In another flask, 3.0 g (4.74 mmol) of zinc stearate and 15 mL of octadecene were added and heated to 100° C. for dissolution, and the solution was stirred in a vacuum for one hour and degassed to prepare a zinc precursor solution. In the flask with the core semiconductor nanoparticles held at 270° C., 3.0 mL (0.95 mmol) of the zinc stearate solution was added and held for 30 minutes. Subsequently, 0.16 g (5.0 mmol) of sulfur and 4.0 mL of trioctylphosphine were added and heated to 150° C. for dissolution to prepare a sulfur/trioctylphosphine solution 1.25 M, 1.0 mL of which was added to the reaction solution and stirred for one hour. Then, 0.22 g (1.1 mmol) of zinc acetate was added and stirred with heating to 100° C. under reduced pressure to be dissolved. The flask was purged with nitrogen again and heated to 230° C., and 0.48 mL (2 mmol) of 1-dodecanethiol was added and the solution was held for one hour. The resulting solution was cooled to room temperature. With addition of ethanol, the solution was centrifuged to precipitate semiconductor nanoparticles, and the supernatant solution was removed. Toluene was further added for dispersion, and ethanol was added again for centrifugation to remove the supernatant solution. The precipitate was dispersed in toluene again to prepare a Zn₃P₂/ZnS solution. The fluorescence emission wavelength peak of the solution was 493 nm, the internal quantum efficiency was 42%, and the absorbance for 450 nm light was 1.2.

### Production Example 4

In a flask, 2.0 mL of oleic acid and 10 mL of 1-octadecene were added and stirred with heating at 100° C. under reduced pressure, and degassed for one hour. Subsequently, the flask was purged with nitrogen and heated to 270° C. When the temperature of the solution was stabilized, 0.2 mL of a tellurium/trioctylphosphine solution separately prepared by adding and dissolving Te in trioctylphosphine and adjusted to 0.3 M, and 0.8 mL of a selenium/trioctylphosphine solution prepared by adding and dissolving Se (selenium) in trioctylphosphine and adjusted to 0.3 M were added to the flask. Further, 0.3 mmol of a diethylzinc solution was added and held at 270° C. for 30 minutes to synthesize core semiconductor nanoparticles. In another flask, 3.0 g (4.74 mmol) of zinc stearate and 15 mL of octadecene were added and heated to 100° C. for dissolution, and the solution was stirred in a vacuum for one hour and degassed to prepare a zinc precursor solution. To the reaction solution at 270° C., 10 mL (3.16 mmol) of the zinc stearate solution and 2.4 mL (0.3 mmol) of a 1.25 M selenium/trioctylphosphine solution prepared in another flask were simultaneously added and stirred for 30 minutes. Subsequently, 4.0 mL of trioctylphosphine was added to 0.16 g (5.0 mmol) of sulfur and heated to 150° C. for dissolution to prepare a sulfur/trioctylphosphine solution 1.25 M, and 1.0 mL of which was added to the reaction solution and stirred for one hour. Then, 0.22 g (1.1 mmol) of zinc acetate was added and stirred with heating to 100° C. under reduced pressure to be dissolved. The flask was purged with nitrogen again and heated to 230° C., 0.48 mL (2 mmol) of 1-dodecanethiol was added, and the solution was held for one hour. The resulting solution was cooled to room temperature and, with addition of ethanol, centrifuged to precipitate semiconductor nanoparticles, and the supernatant solution was removed. Toluene was further added for dispersion, and ethanol was added again for centrifugation to remove the supernatant solution. The precipitate was dispersed in toluene again to prepare a ZnTeSe/ZnSe/ZnS solution. The fluorescence emission wavelength peak of the solution was 498 nm, the internal quantum efficiency was 45%, and the absorbance for 450 nm light was 1.4.

### Production Example 5

In a flask, 0.033 g (0.20 mmol) of silver acetate (I), 0.058 g (0.20 mmol) of indium acetate, 0.65 mL (2.7 mmol) of 1-dodecanethiol, and 4.0 ml of oleylamine were added and stirred with heating at 100° C. under reduced pressure, and degassed for one hour. Subsequently, the flask was purged with nitrogen, heated to 200° C., and held for 20 minutes. Then, the flask was heated to 230° C. and then 1.0 mL of a sulfur/trioctylphosphine solution 1.25 M prepared was added to the reaction solution and stirred for one hour. Finally, 0.066 g (0.36 mmol) of zinc acetate, 0.24 ml (0.76 mmol) of oleic acid, and 0.15 ml of oleylamine were added to the flask and stirred with heating at 230° C. for one hour. The resulting solution was cooled to room temperature and, with addition of ethanol, centrifuged to precipitate semiconductor nanoparticles, and the supernatant solution was removed. Toluene was further added for dispersion, and ethanol was added again for centrifugation to remove the supernatant solution. The precipitate was dispersed in toluene again to prepare a AgInS₂/ZnS solution. The fluorescence emission wavelength peak of the solution was 597 nm, the internal quantum efficiency was 56%, and the absorbance for 450 nm light was 1.0.

### Production and Evaluation of Wavelength Converter

To produce the wavelength converter containing the first semiconductor nanoparticle and the second semiconductor nanoparticle, the first semiconductor nanoparticle was selected from the semiconductor nanoparticle of Production Example 1 or Production Example 2, and the second semiconductor nanoparticle was selected from the semiconductor nanoparticle of Production Example 3 or Production Example 4 or Production Example 5. These semiconductor nanoparticles were adjusted to desired mass ratios with respect to 1.0 ml of a toluene solvent to prepare a wavelength converter.

### (Measurement)

In fluorescence emission characteristics evaluation of semiconductor nanoparticles in the wavelength converters of Examples and Comparative Examples, the absorptance for excitation light at an excitation wavelength of 450 nm, the emission wavelength peak, and the emission intensity of the emission wavelength peak were measured using a quantum efficiency measurement system (QE-2100: manufactured by Otsuka Electronics Co., Ltd.).

### Example 1

A dispersion liquid of a wavelength converter was prepared, in which 1.0 mg of semiconductor nanoparticles synthesized in Production Example 1 and 0.10 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 52.1%, and the emission intensity I_{1b} of light with wavelength λ₁=534 nm was 1.21×10⁻³.

### Example 2

A dispersion liquid of a wavelength converter was prepared, in which 1.0 mg of semiconductor nanoparticles synthesized in Production Example 1 and 0.20 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 59.5%, and the emission intensity I_{1b} of light with wavelength λ₁=534 nm was 1.38×10⁻³.

### Example 3

A dispersion liquid of a wavelength converter was prepared, in which 1.0 mg of semiconductor nanoparticles synthesized in Production Example 1 and 0.30 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 66.1%, and the emission intensity I_{1b} of light with wavelength λ₁=534 nm was 1.52×10⁻³.

### Example 4

A dispersion liquid of a wavelength converter was prepared, in which 1.1 mg of semiconductor nanoparticles synthesized in Production Example 1 and 0.33 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 74.2%, and the emission intensity I_{1b} of light with wavelength λ₁=534 nm was 1.69×10⁻³.

### Example 5

A dispersion liquid of a wavelength converter was prepared, in which 1.2 mg of semiconductor nanoparticles synthesized in Production Example 1 and 0.36 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 81.6%, and the emission intensity I_{1b} of light with wavelength λ₁=534 nm was 1.84×10⁻³.

### Example 6

A dispersion liquid of a wavelength converter was prepared, in which 1.3 mg of semiconductor nanoparticles synthesized in Production Example 1 and 0.39 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 87.0%, and the emission intensity I_{1b} of light with wavelength λ₁=534 nm was 2.01×10⁻³.

### Example 7

A dispersion liquid of a wavelength converter was prepared, in which 1.4 mg of semiconductor nanoparticles synthesized in Production Example 1 and 0.42 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 92.6%, and the emission intensity I_{1b} of light with wavelength λ₁=534 nm was 2.11×10⁻³.

### Example 8

A dispersion liquid of a wavelength converter was prepared, in which 1.6 mg of semiconductor nanoparticles synthesized in Production Example 1 and 0.48 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 95.1%, and the emission intensity I_{1b} of light with wavelength λ₁=534 nm was 2.20×10⁻³.

### Example 9

A dispersion liquid of a wavelength converter was prepared, in which 1.0 mg of semiconductor nanoparticles synthesized in Production Example 2 and 0.30 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 64.2%, and the emission intensity I_{1b} of light with wavelength λ₁=622 nm was 1.39×10⁻³.

### Example 10

A dispersion liquid of a wavelength converter was prepared, in which 1.4 mg of semiconductor nanoparticles synthesized in Production Example 2 and 0.42 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 85.7%, and the emission intensity I_{1b} of light with wavelength λ₁=622 nm was 1.82×10⁻³.

### Example 11

A dispersion liquid of a wavelength converter was prepared, in which 1.6 mg of semiconductor nanoparticles synthesized in Production Example 2 and 0.48 mg of semiconductor nanoparticles synthesized in Production Example 3 were dispersed in 1.0 mL of a toluene solution. When the wavelength converter was irradiated with blue light of 450 nm and with an excitation photon number N₀=4.7×10¹¹, the absorptance for blue light was 90.4%, and the emission intensity I_{1b} of light with wavelength λ₁=622 nm was 1.96×10⁻³.

### Example 12

A dispersion liquid of a wavelength converter was prepared, in which 1.3 mg of semiconductor nanoparticles synthesized in Production Example 1 and 0.39 mg of semiconductor nanoparticles synthesized in Production Example 4 were dispersed in 1.0 mL of a toluene solution. When the wavelength converter was irradiated with blue light of 450 nm and with an excitation photon number N₀=4.7×10¹¹, the absorptance for blue light was 90.7%, and the emission intensity I_{1b} of light with wavelength λ₁=534 nm was 2.09×10⁻³.

### Example 13

A dispersion liquid of a wavelength converter was prepared, in which 1.4 mg of semiconductor nanoparticles synthesized in Production Example 1 and 0.42 mg of semiconductor nanoparticles synthesized in Production Example 4 were dispersed in 1.0 mL of a toluene solution. When the wavelength converter was irradiated with blue light of 450 nm and with an excitation photon number N₀=4.7×10¹¹, the absorptance for blue light was 93.5%, and the emission intensity I_{1b} of light with wavelength λ₁=534 nm was 2.13×10⁻³.

### Example 14

A dispersion liquid of a wavelength converter was prepared, in which 1.4 mg of semiconductor nanoparticles synthesized in Production Example 2 and 0.42 mg of semiconductor nanoparticles synthesized in Production Example 4 were dispersed in 1.0 mL of a toluene solution. When the wavelength converter was irradiated with blue light of 450 nm and with an excitation photon number N₀=4.7×10¹¹, the absorptance for blue light was 87.0%, and the emission intensity I_{1b} of light with wavelength λ₁=622 nm was 1.87×10⁻³.

### Example 15

A dispersion liquid of a wavelength converter was prepared, in which 1.6 mg of semiconductor nanoparticles synthesized in Production Example 2 and 0.48 mg of semiconductor nanoparticles synthesized in Production Example 4 were dispersed in 1.0 mL of a toluene solution. When the wavelength converter was irradiated with blue light of 450 nm and with an excitation photon number N₀=4.7×10¹¹, the absorptance for blue light was 91.0%, and the emission intensity I_{1b} of light with wavelength λ₁=622 nm was 1.98×10⁻³.

### Example 16

A dispersion liquid of a wavelength converter was prepared, in which 1.4 mg of semiconductor nanoparticles synthesized in Production Example 2 and 0.42 mg of semiconductor nanoparticles synthesized in Production Example 5 were dispersed in 1.0 mL of a toluene solution. When the wavelength converter was irradiated with blue light of 450 nm and with an excitation photon number N₀=4.7×10¹¹, the absorptance for blue light was 79.8%, and the emission intensity I_{1b} of light with wavelength λ₁=622 nm was 1.80×10⁻³.

### Example 17

A dispersion liquid of a wavelength converter was prepared, in which 1.8 mg of semiconductor nanoparticles synthesized in Production Example 2 and 0.54 mg of semiconductor nanoparticles synthesized in Production Example 5 were dispersed in 1.0 mL of a toluene solution. When the wavelength converter was irradiated with blue light of 450 nm and with an excitation photon number N₀=4.7×10¹¹, the absorptance for blue light was 90.2%, and the emission intensity I_{1b} of light with wavelength λ₁=622 nm was 1.95×10⁻³.

### Comparative Example 1

A dispersion liquid of a wavelength converter was prepared, in which 1.0 mg of semiconductor nanoparticles synthesized in Production Example 1 were dispersed in 1.0 mL of a toluene solution. When the wavelength converter was irradiated with blue light of 450 nm and with an excitation photon number N₀=4.7×10¹¹, the absorptance for blue light was 43.6%, and the emission intensity I₁ₐ of light with wavelength λ₁=534 nm was 1.05×10⁻³.

### Comparative Example 2

A dispersion liquid of a wavelength converter was prepared, in which 1.4 mg of semiconductor nanoparticles synthesized in Production Example 1 were dispersed in 1.0 mL of a toluene solution. When the wavelength converter was irradiated with blue light of 450 nm and with an excitation photon number N₀=4.7×10¹¹, the absorptance for blue light was 60.8%, and the emission intensity I₁ₐ of light with wavelength λ₁=534 nm was 1.41×10⁻³.

### Comparative Example 3

A dispersion liquid of a wavelength converter was prepared, in which 1.0 mg of semiconductor nanoparticles synthesized in Production Example 2 were dispersed in 1.0 mL of a toluene solution. When the wavelength converter was irradiated with blue light of 450 nm and with an excitation photon number N₀=4.7×10¹¹, the absorptance for blue light was 41.8%, and the emission intensity I₁ₐ of light with wavelength λ₁=622 nm was 0.96×10⁻³.

### Comparative Example 4

A dispersion liquid of a wavelength converter was prepared, in which 1.4 mg of semiconductor nanoparticles synthesized in Production Example 2 were dispersed in 1.0 mL of a toluene solution. When the wavelength converter was irradiated with blue light of 450 nm and with an excitation photon number N₀=4.7×10¹¹, the absorptance for blue light was 58.5%, and the emission intensity I₁ₐ of light with wavelength λ₁=622 nm was 1.30×10⁻³.

The evaluation results of Examples 1 to 17 and Comparative Examples 1 to 4 above are listed in Table 1.

TABLE 1

| | First | Weight | Second | Weight | | | Excitation | Excitation | | Emission |
|---|---|---|---|---|---|---|---|---|---|---|
| | semiconductor | W₁ of | semiconductor | W₂ of | Weight | Excitation | photon | light | Fluorescence | intensity |
| | nanoparticle | QD₁ | nanoparticle | QD₂ | ratio | wavelength | number | absorptance | wavelength λ₁ | (×10⁻³) of |
| | (QD₁) | (mg) | (QD₂) | (mg) | W₂/W₁ | (nm) | (×10¹¹) | (%) | (nm) | wavelength λ₁ |
| Ex. 1 | Production | 1.0 | Production | 0.10 | 0.10 | 450 | 4.7 | 52.1 | 534 | 1.21 |
| | Example 1 | | Example 3 | | | | | | | |
| Ex. 2 | Production | 1.0 | Production | 0.20 | 0.20 | 450 | 4.7 | 59.5 | 534 | 1.38 |
| | Example 1 | | Example 3 | | | | | | | |
| Ex. 3 | Production | 1.0 | Production | 0.30 | 0.30 | 450 | 4.7 | 66.1 | 534 | 1.52 |
| | Example 1 | | Example 3 | | | | | | | |
| Ex. 4 | Production | 1.1 | Production | 0.33 | 0.30 | 450 | 4.7 | 74.2 | 534 | 1.69 |
| | Example 1 | | Example 3 | | | | | | | |
| Ex. 5 | Production | 1.2 | Production | 0.36 | 0.30 | 450 | 4.7 | 81.6 | 534 | 1.84 |
| | Example 1 | | Example 3 | | | | | | | |
| Ex. 6 | Production | 1.3 | Production | 0.39 | 0.30 | 450 | 4.7 | 87.0 | 534 | 2.01 |
| | Example 1 | | Example 3 | | | | | | | |
| Ex. 7 | Production | 1.4 | Production | 0.42 | 0.30 | 450 | 4.7 | 92.6 | 534 | 2.11 |
| | Example 1 | | Example 3 | | | | | | | |
| Ex. 8 | Production | 1.6 | Production | 0.48 | 0.30 | 450 | 4.7 | 95.1 | 534 | 2.20 |
| | Example 1 | | Example 3 | | | | | | | |
| Ex. 9 | Production | 1.0 | Production | 0.30 | 0.30 | 450 | 4.7 | 64.2 | 622 | 1.39 |
| | Example 2 | | Example 3 | | | | | | | |
| Ex. 10 | Production | 1.4 | Production | 0.42 | 0.30 | 450 | 4.7 | 85.7 | 622 | 1.82 |
| | Example 2 | | Example 3 | | | | | | | |
| Ex. 11 | Production | 1.6 | Production | 0.48 | 0.30 | 450 | 4.7 | 90.4 | 622 | 1.96 |
| | Example 2 | | Example 3 | | | | | | | |
| Ex. 12 | Production | 1.3 | Production | 0.39 | 0.30 | 450 | 4.7 | 90.7 | 534 | 2.09 |
| | Example 1 | | Example 4 | | | | | | | |
| Ex. 13 | Production | 1.4 | Production | 0.42 | 0.30 | 450 | 4.7 | 93.5 | 534 | 2.13 |
| | Example 1 | | Example 4 | | | | | | | |
| Ex. 14 | Production | 1.4 | Production | 0.42 | 0.30 | 450 | 4.7 | 87.0 | 622 | 1.87 |
| | Example 2 | | Example 4 | | | | | | | |
| Ex. 15 | Production | 1.6 | Production | 0.48 | 0.30 | 450 | 4.7 | 91.0 | 622 | 1.98 |
| | Example 2 | | Example 4 | | | | | | | |
| Ex. 16 | Production | 1.4 | Production | 0.42 | 0.30 | 450 | 4.7 | 79.8 | 622 | 1.80 |
| | Example 2 | | Example 5 | | | | | | | |
| Ex. 17 | Production | 1.8 | Production | 0.54 | 0.30 | 450 | 4.7 | 90.2 | 622 | 1.95 |
| | Example 2 | | Example 5 | | | | | | | |
| Comp. | Production | 1.0 | None | 0 | 0 | 450 | 4.7 | 43.6 | 534 | 1.05 |
| EX. 1 | Example 1 | | | | | | | | | |
| Comp. | Production | 1.4 | None | 0 | 0 | 450 | 4.7 | 60.8 | 534 | 1.41 |
| EX. 2 | Example 1 | | | | | | | | | |
| Comp. | Production | 1.0 | None | 0 | 0 | 450 | 4.7 | 41.8 | 622 | 0.96 |
| EX. 3 | Example 2 | | | | | | | | | |
| Comp. | Production | 1.4 | None | 0 | 0 | 450 | 4.7 | 58.5 | 622 | 1.30 |
| EX. 4 | Example 2 | | | | | | | | | |

As listed in Table 1, the comparison of the results of Examples 1 to 8 and Examples 12 and 13 with the results of Comparative Examples 1 and 2 indicated that the absorptance for blue light and the emission intensity at a wavelength 534 nm when the wavelength converter of Production Example 1 and, Production Example 3 or Production Example 4 was irradiated with light with a wavelength of 450 nm exhibited larger values than the absorptance for blue light and the relative emission intensity when the wavelength converter including semiconductor nanoparticles of Production Example 1 alone was irradiated with light with a wavelength of 450 nm, and the light extraction efficiency of green light was improved.

Furthermore, in Table 1, the comparison of the results of Examples 9 to 11 and Examples 14 to 17 with the results of Comparative Examples 3 and 4 indicated that the absorptance for blue light and the emission intensity at a wavelength 622 nm when the wavelength converter of Production Example 2 and, Production Example 3 or Production Example 4 or Production Example 5 was irradiated with light with a wavelength of 450 nm exhibited larger values than the absorptance for blue light and the emission intensity when the wavelength converter including semiconductor nanoparticles of Production Example 2 alone was irradiated with light with a wavelength of 450 nm, and the light extraction efficiency of red light was improved.

As for Examples 7, 8, 11 to 13, 15, and 17, the absorptance for blue light was 90% or more, and the emission intensity was 1.95×10⁻³ or more, indicating that the absorptance particularly for blue excitation light was improved and the light extraction efficiency was improved.

These results have suggested that the wavelength converter according to the present invention has improved absorptance for blue excitation light and has improved light extraction efficiency.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A wavelength converter comprising, as semiconductor nanoparticles, a first semiconductor nanoparticle that converts light with a wavelength of 450 nm into light with a wavelength 2 nm, and a second semiconductor nanoparticle that converts light with a wavelength of 450 nm into light with a wavelength 22 nm, wherein
the wavelength A and the wavelength λ₂ satisfy λ₁>λ₂>450, and
a relation between an emission intensity I_{1b} and an emission intensity I₁ₐ satisfies I₁ₐ<I_{1b}, where I_{1b} is an emission intensity at the wavelength λ₁ when the wavelength converter comprising the first semiconductor nanoparticle and the second semiconductor nanoparticle is irradiated with light with a wavelength of 450 nm and an excitation photon number N₀, and I₁ₐ is an emission intensity at the wavelength λ₁ when a wavelength converter comprising only the first semiconductor nanoparticle as a semiconductor nanoparticle is irradiated with the light with a wavelength of 450 nm and an excitation photon number N₀.

2. The wavelength converter according to claim 1, wherein the wavelength λ₁ is included in a range of 510 to 550 nm or 610 to 650 nm.

3. The wavelength converter according to claim 1, wherein the wavelength λ₁ is included in a range of 510 to 550 nm, and the wavelength λ₂ is included in a range of 480 to 510 nm.

4. The wavelength converter according to claim 1, wherein the wavelength λ₁ is included in a range of 510 to 550 nm, and the wavelength λ₂ is included in a range of 490 to 500 nm.

5. The wavelength converter according to claim 1, wherein the wavelength λ₁ is included in a range of 610 to 650 nm, and the wavelength λ₂ is included in a range of 480 to 600 nm.

6. The wavelength converter according to claim 1, wherein the wavelength λ₁ is included in a range of 610 to 650 nm, and the wavelength λ₂ is included in 490 to 500 nm or 590 to 600 nm.

7. The wavelength converter according to claim 1, wherein the first semiconductor nanoparticle is a semiconductor nanoparticle comprising a core semiconductor containing In and P, and a single or multiple shell semiconductors covering the core semiconductor.

8. The wavelength converter according to claim 7, wherein the shell semiconductor of the first semiconductor nanoparticle comprises any one semiconductor or a mixed crystal of a plurality of semiconductors selected from the group consisting of ZnS, ZnSe, ZnTe, AlN, AIP, AlAs, AlSb, GaN, GaP, GaAs, GaSb, InN, InP, InAs, and InSb.

9. The wavelength converter according to claim 1, wherein the second semiconductor nanoparticle comprises a core semiconductor containing Zn, Se, and Te, and a single or multiple shell semiconductors covering the core semiconductor.

10. The wavelength converter according to claim 1, wherein the second semiconductor nanoparticle comprises a core semiconductor containing Zn and P, and a single or multiple shell semiconductors covering the core semiconductor.

11. The wavelength converter according to claim 1, wherein the second semiconductor nanoparticle comprises a core semiconductor that is a compound with a chalcopyrite structure, and a single or multiple shell semiconductors covering the core semiconductor.

12. The wavelength converter according to claim 1, wherein the second semiconductor nanoparticle comprises a core semiconductor comprising any one semiconductor or a mixed crystal of a plurality of semiconductors selected from the group consisting of AgGaS₂, AgInS₂, AgGaSe₂, AgInSe₂, CuGaS₂, CuGaSe₂, CuInS₂, CuInS₂, ZnSiP₂, and ZnGeP₂, and a single or multiple shell semiconductors covering the core semiconductor.

13. The wavelength converter according to claim 9, wherein the shell semiconductor of the second semiconductor nanoparticle comprises a II-VI compound semiconductor.

14. The wavelength converter according to claim 9, wherein the shell semiconductor of the second semiconductor nanoparticle comprises any one semiconductor or a mixed crystal of a plurality of semiconductors selected from the group consisting of ZnSe and ZnS.

15. The wavelength converter according to claim 1, wherein a dispersion liquid in which 1.0 mg of the first semiconductor nanoparticle is dispersed in 1.0 mL of a solvent has an absorbance of 0.7 or more at an optical path length of 1 cm for light with a wavelength of 450 nm.

16. The wavelength converter according to claim 1, wherein a dispersion liquid in which 1.0 mg of the second semiconductor nanoparticle is dispersed in 1.0 mL of a solvent has an absorbance of 1.0 or more at an optical path length of 1 cm for light with a wavelength of 450 nm.

17. The wavelength converter according to claim 1, wherein a dispersion liquid in which 1.0 mg of the second semiconductor nanoparticle is dispersed in 1.0 mL of a solvent has an absorbance of 1.2 or more at an optical path length of 1 cm for light with a wavelength of 450 nm.

18. The wavelength converter according to claim 1, wherein a dispersion liquid in which 1.0 mg of the second semiconductor nanoparticle is dispersed in 1.0 mL of a solvent has an absorbance of 1.4 or more at an optical path length of 1 cm for light with a wavelength of 450 nm.

19. The wavelength converter according to claim 1, wherein the first semiconductor nanoparticle has an internal quantum efficiency of 70% or more.

20. The wavelength converter according to claim 1, wherein the second semiconductor nanoparticle has an internal quantum efficiency of 40% or more.

21. The wavelength converter according to claim 1, wherein a mass ratio of the second semiconductor nanoparticle to the first semiconductor nanoparticle has a value of 0.3 or less.

22. A wavelength conversion material in which the wavelength converter according to claim 1 is dispersed in a resin.
